(19) United States
(12) Patent Application Publication
(10) Pub. No.: US 2010/0052191 A1
(43) Pub. Date: Mar. 4, 2010

(54) Metrology Mark with Elements Arranged in a Matrix, Method of Manufacturing Same and Alignment Method

(75) Inventors: Sven Trogisch, Dresden (DE); Joerg Tschischgale, Dresden (DE); Markus Bender, Dresden (DE)

Correspondence Address: EDELL, SHAPIRO & FINNAN, LLC, 1901 RESEARCH BLVD., SUITE 400, ROCKVILLE, MD, 20850, US

(73) Assignee: QIMONDA AG, Munich (DE)

(21) Appl. No.: 12/201,605

(22) Filed: Aug. 29, 2008

(51) Int. Cl. H01L 23/544; H01L 21/76

(52) U.S. Cl. 257/797; 438/401; 257/E23.179

(57) ABSTRACT

A method of manufacturing an integrated circuit provides a metrology mark (e.g., alignment mark or overlay mark). The method includes forming a first plurality of first structures arranged in a matrix in a substrate. Portions of the matrix are covered with a mask such that first portions of the matrix are left exposed and second portions of the matrix are covered. Signal response properties of exposed ones of the first structures in the matrix are altered to form a metrology mark. The metrology mark includes first and second mark portions with different signal response properties and which are aligned to a virtual grid. The evaluation of precisely positioned metrology marks may be improved with low impact on process complexity.

### BACKGROUND

The manufacture of semiconductor devices involves lithography processes for transferring a mask pattern into a photosensitive film that covers a wafer surface and that is sensitive to the exposure radiation. In and on the wafer, structures and patterns are formed in a plurality of layers, wherein the patterns in the various layers have to be aligned to each other. Various types of metrology marks on the wafer are used for process control purposes. Alignment marks on the wafer are evaluated in order to adjust the wafer in or to a lithography exposure apparatus. The placement of overlay marks relative to each other gives information on a displacement or misalignment between the respective layers. The displacement information may be fed back or fed forward within the wafer process flow. Typical embodiments of overlay marks include box-in-box-marks with boxes formed of four lines arranged along the sides of a rectangle, wherein an outer box may be formed in a first layer and a smaller, inner box may be formed in a second layer. The first and the second layers are precisely registered and the masks and the wafer have been perfectly aligned to each other in the respective exposure process, when the resulting box-in-box alignment mark is concentric. Metrology marks may be provided, for example, in a kerf region between neighboring chip areas.

The more precise the position of a metrology mark may be determined and the narrower a tolerance range for a displacement of the metrology mark from a target position can be assumed, the more precise a wafer may be aligned or a misalignment between the respective layers may be determined.

A need exists for metrology marks, methods of manufacturing integrated circuits comprising such metrology marks and for alignment methods facilitating the manufacturing of an integrated circuit with improved device performance and/or at improved yield.

### SUMMARY

A method of manufacturing an integrated circuit with a metrology mark is described herein. The method includes forming first structures arranged in a matrix in a substrate. A mask (e.g., hard mask) covers first portions of the matrix and leaves second portions uncovered. The signal response properties (e.g., reflectivity) of uncovered ones of the first structures in the matrix are altered to form a metrology mark comprising first and second mark portions of different signal response properties and which are aligned to the same grid. The evaluation of precisely positioned metrology marks may be improved with low impact on process complexity.

The above and still further features and advantages of the present invention will become apparent upon consideration of the following definitions, descriptions and descriptive figures of specific embodiments thereof, wherein like reference numerals in the various figures are utilized to designate like components. While these descriptions go into specific details of the invention, it should be understood that variations may and do exist and would be apparent to those skilled in the art based on the descriptions herein.

### BRIEF DESCRIPTION OF THE DRAWINGS

Features and advantages of embodiments will become apparent from the following description with reference to the accompanying drawings. The drawings are not to scale. Emphasis is placed upon illustrating the principles. Features of embodiments illustrated in the various Figures may be combined with each other.

FIG. 1A is a schematic cross sectional view of a first and a second substrate section including trench-like first structures for illustrating a method of forming a metrology mark according to an embodiment.

FIG. 1B is a schematic cross sectional view of the substrate sections of FIG. 1A after recessing a subset of the first structures in the first substrate section.

FIG. 1C is a schematic cross sectional view of the substrate sections of FIG. 1B after altering the signal response properties of the subset of the first structures in the first substrate section.

FIG. 1D is a schematic plan view on the substrate with a first substrate section including a metrology mark comprising densely spaced mark sections and with a second substrate section according a further embodiment.

FIG. 2A illustrates a schematic cross sectional view of a further substrate comprising gate-like first structures in a first and a second substrate section for illustrating a method of forming a metrology mark according to another embodiment.

FIG. 2B illustrates a schematic cross sectional view of the substrate sections according to FIG. 2A after recessing a subset of the first structures in the first substrate section.

FIG. 2C illustrates a schematic cross sectional view of the substrate sections of FIG. 2B after changing the signal response properties of the exposed subset of first structures.

FIG. 2D is a schematic plan view of a substrate with a metrology mark including widely spaced mark sections according to another embodiment.

FIG. 3A is a schematic plan view of an overlay mark with a box-shaped arrangement of first and second mark portions according to a further embodiment.

FIG. 3B is a schematic plan view of an overlay mark with cross-shaped arrangement of first and second mark portions.

FIG. 3C is a schematic plan view of a metrology mark with stripe-shaped arrangement of first and second mark portions.

FIG. 4A is a simplified flow chart illustrating a method of manufacturing an integrated circuit comprising an alignment mark in accordance with another embodiment.

FIG. 4B is a simplified flow chart that illustrates a method of aligning wafers in course of the manufacture of integrated circuits in accordance with other embodiments.

### DETAILED DESCRIPTION

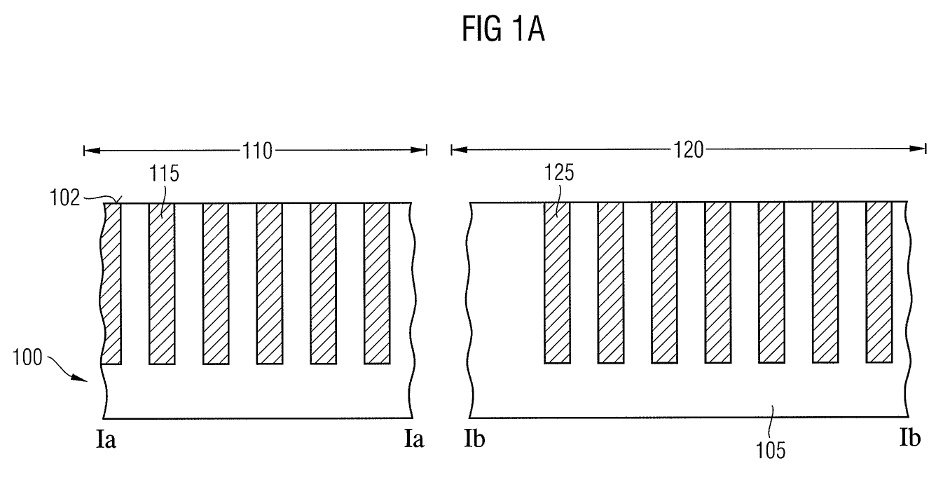

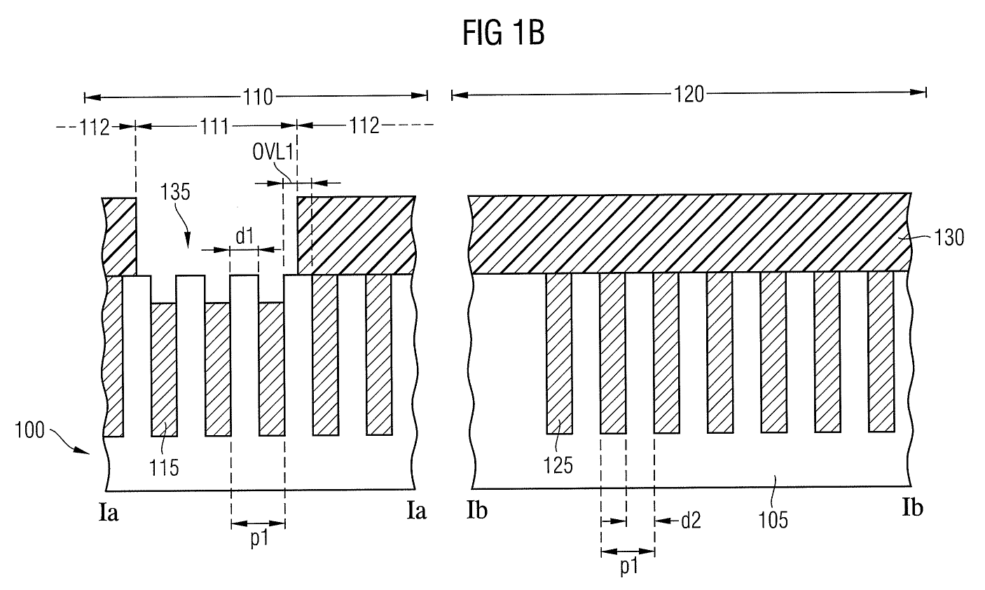

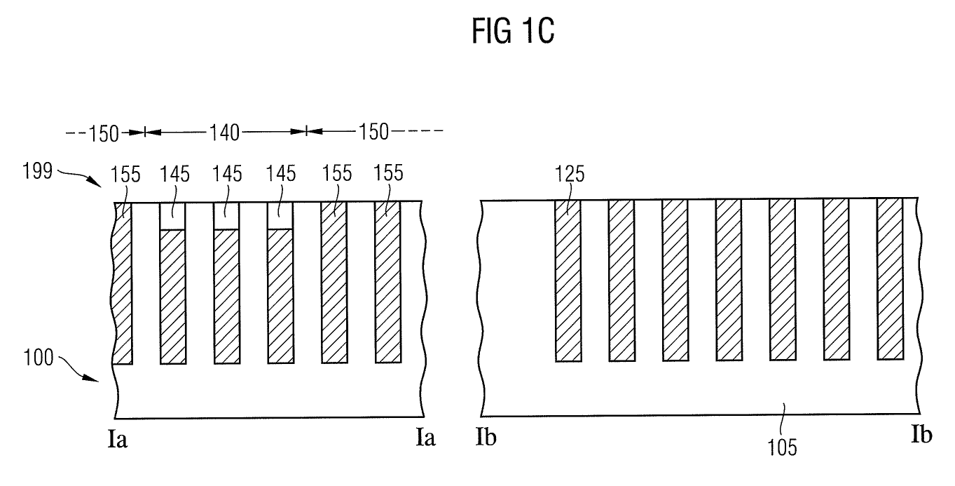

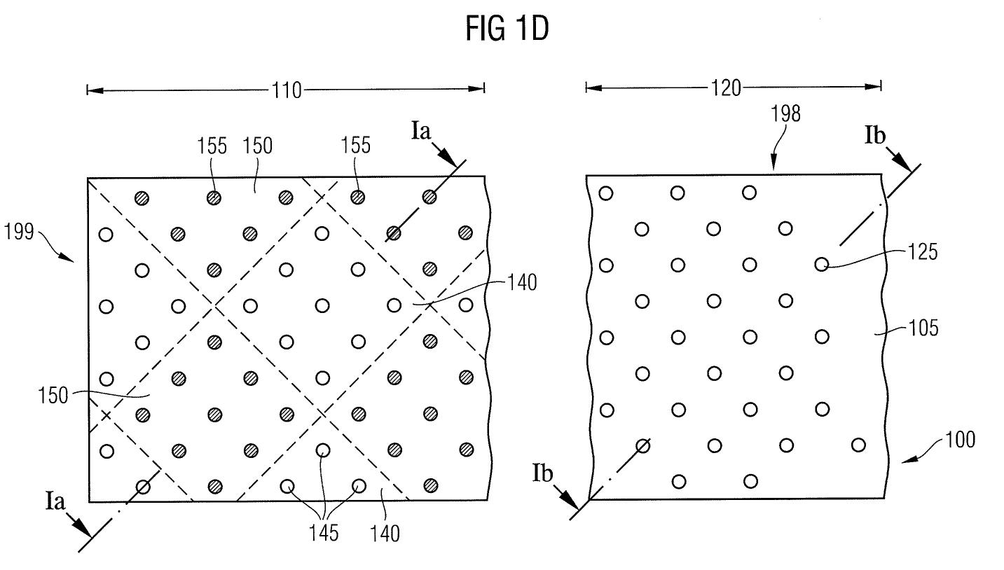

FIG. 1A refers to a portion of a first substrate section 110 and a portion of a second substrate section 120 of a substrate 100. The substrate 100 may be a pre-processed workpiece (e.g., a carrier consisting of or comprising glass or plastic; or a semiconductor wafer). According to an embodiment, the substrate 100 may be a preprocessed single crystalline silicon wafer or a silicon-on-insulator (SoI) wafer and may include further doped and undoped sections, epitaxial semiconductor layers as well as further conductive and insulating structures that have previously been fabricated. The first and second substrate sections 110, 120 may correspond to portions of a chip area which include dense patterns of first structures 115, 125 embedded in a layer or substrate portion 105. The first structures 115, 125 may be conductive structures formed within an insulating layer, doped regions within a layer or a semiconducting substrate portion, insulating structures introduced into a semiconducting layer or a semiconducting substrate portion, or complex structures, for example, capacitors, gate electrode stacks, multilayered conductive lines or vias embedded in an insulating template. The first substrate section 110 may correspond to a kerf area of the substrate 100, in which the substrate 100 is sawed for decollating or separating individual semiconductor devices, for example, integrated circuits (e.g., DRAMs (dynamic random access memories), PCRAMs (phase-change random access memories), FeRAMs (ferroelectric random access memories), FBRAMs (floating-body random access memories), MRAMs (magneto-resistive random access memories) or EEPROMs (electrically erasable random access memories)), highly integrated circuits containing embedded memory (e.g., DRAM, PCRAM, FeRAM, FBRAM, MRAM, EEPROM), microprocessors, microcontrollers, complex logic circuits, ASICs (application specific integrated circuits) or mixed signal devices.

A first plurality of first structures 115 is formed in the first substrate section 110, for example, contemporaneously with a second plurality of first structures 125 in a second substrate section 120. The first structures 115, 125 in the first and the second substrate sections 110, 120 may result from the same processes and may be approximately identical in view of the dimensions, the cross-sections, the cross-sectional areas, and the materials. From the second plurality of first structures 125 electric functional structures emerge, for example, while the first plurality of first structures 115 is used for alignment, measurement, process control and overlay adjustment. A measurement signal obtained from the first structures, for example, a signal based on their optical, inductive or capacitive contrast can be too weak to reliably determine the position of the first structures with sufficient precision.

Referring to FIG. 1B, a mask 130 may be provided above the first and the second substrate sections 110, 120. The mask 130 covers second portions 112 of the first substrate section 110 and covers the second substrate section 120 completely, while leaving first portions 111 of the first substrate section 110 uncovered (i.e., exposed). The mask 130 may be a resist film or a mask system comprising, for example, silicon oxide, silicon nitride, amorphous silicon, polysilicon or carbon, which is patterned through lithography techniques.

According to FIG. 1B, the mask 130 comprises openings 135 above the first portions 111 of the first substrate section 110. The allowable misalignment or overlay tolerance (OVL1) is defined by the distance between neighboring first structures 115, 125. The first structures 115, 125 may be arranged at the same pitch p1 in the first and second substrate sections 110, 120. The first structures 115 in the first substrate section 110 have a first distance d1 to each other along at least one dimension and the first structures 125 in the second substrate section 120 have a second distance d2 to each other along the same dimension. The second distance d2 may be equal to the first distance d1 or may slightly deviate from d1. In accordance to other embodiments, the first structures 115, 125 are arranged at a first pitch along a first direction and at a second, different pitch along a second direction orthogonal to the first direction within each substrate portion 111, 112.

Referring to FIG. 1C, the properties of the first structures 115 may be selectively altered in the exposed first portions 111 to that in the covered second portions 112. According to the illustrated embodiment, the signal response properties (e.g., the reflectivity) of the first structures 115 in the first portions 111 with reference to an inspection signal is altered by replacing a first material forming an upper portion of the first structures 115 with a second material that may provide a higher optical, capacitive or inductive contrast versus an embedding material than the first material. The embedding material may be, for example, that of layer or substrate portion 105. An upper section of the respective first structures 115 may be removed, for example, by a wet etch or a reactive ion-beam etch. Then, the mask 130 may be removed and the second material may be deposited that may fill the grooves formed by the preceding etch. Portions of the second material deposited outside the grooves may be removed, for example, via a CMP (chemical mechanical polishing)-method. According to other embodiments, the removal of the second material deposited outside the grooves is omitted and the second material images the covered topology on its top surface. The undulated sub-regions of the top surface of the second material identify the first portions 111 and discriminate them against the second portions 112 which may be identified by flat sub-regions of the top surface of the second material, which may be, for example, a metal or metal compound (e.g., tungsten).

In accordance with other embodiments, impurities may be introduced into a surface section of the exposed first structures via, for example, an ion beam implant. In accordance with further embodiments, the exposed sections of the material forming the first structures 115 may be chemically altered through a chemical reaction by supplying a suitable chemical reactant.

FIG. 1C illustrates on the left hand side a metrology mark 199 resulting from the process described above and comprising first elements 145 in first mark portions 140 and second elements 155, which correspond to unaltered first structures 115, in second mark portions 150. The first elements 145 are approximately identical to the second elements 155 with respect to their lower portions. Upper portions of the first elements 145 are formed from a material that is different from the material forming the upper portions of the second elements 155 such that, for example, an optical contrast of the metrology mark 199 is improved, for example, at an illumination wavelength equal to or less than 1000 nm (e.g., about 532 nm or about 633 nm). The edges of the first and second mark portions 140, 150 are self-aligned with respect to the first structures 115 of FIG. 1 A, which form a precise grid relaxing the overlay requirements for the formation of the mask openings 135 of FIG. 1B. In the first substrate section 110, one or more of the first structures 115 may be omitted between neighboring first and second portions 111, 112. Accordingly, neighboring first structures 115 of neighboring portions 111, 112 are spaced at a distance which is equal to the first distance d1 plus an integer multiple of the first pitch p1.

FIG. 1D refers to a planar top view on the substrate 100 as illustrated in FIG. 1C. On the left hand side, FIG. 1D illustrates a portion of a metrology mark 199 in a first substrate section 110. The metrology mark 199 may comprise first and second mark portions 140, 150 arranged in a regular pattern which may include, for example, identical cells arranged at a constant pitch or which may be axis-symmetric. The pattern may be, for example, a checkerboard pattern with first and second mark sections 140, 150 arranged along two dimensions in alternating order. The mark portions 140, 150 may be rectangles (e.g., squares). In accordance with other embodiments, the first and second mark portions 140, 150 may be arranged to boxes, wherein a plurality of first mark sections 140 form lines arranged along the sides of a rectangle which is filled and surrounded with second mark portions 150, or vice versa. The first mark portions 140 include first elements 145 having, for example, optical properties that differ from that of second elements 155 arranged in the second mark portions 150.

The elements 145, 155 of the metrology mark 199 are aligned with respect to a second plurality of first structures 125 in a second section 120 of the substrate 100 as illustrated on the right hand side of FIG. 1D. The first structures 125 in the second substrate section 120 may be, for example, complex electric functional devices (e.g., capacitors, contacts, doped areas, gate electrodes or sub-structures thereof) and may be aligned to a first virtual regular grid. The metrology mark 199 comprises elements 145, 155 aligned with respect to a second virtual regular grid which may have the same mesh dimensions as the first grid. According to another embodiment, the first and second grids are portions of a superordinate virtual grid. The contrast which the metrology mark delivers is high since different materials determine a response to an inspection signal within the metrology mark 199. The edges of different sections of the metrology mark 199 are defined by the first virtual grid along which the elements 145, 155 are formed. As the fabrication of the metrology mark 199 is closely connected with the fabrication of the elements to which they have to be aligned, their placement is almost invariant versus process variations. Due to the use of different materials, a high contrast in the response to an inspection signal (e.g., an optical signal in the wavelength range of visible light or shorter) may be provided.

Measuring the metrology mark 199, for example, by scanning with radiation of, for example, 532 nm wavelength, the position of first and second mark portions 140, 150 and of first and second mark elements may be determined with high precision and reliability.

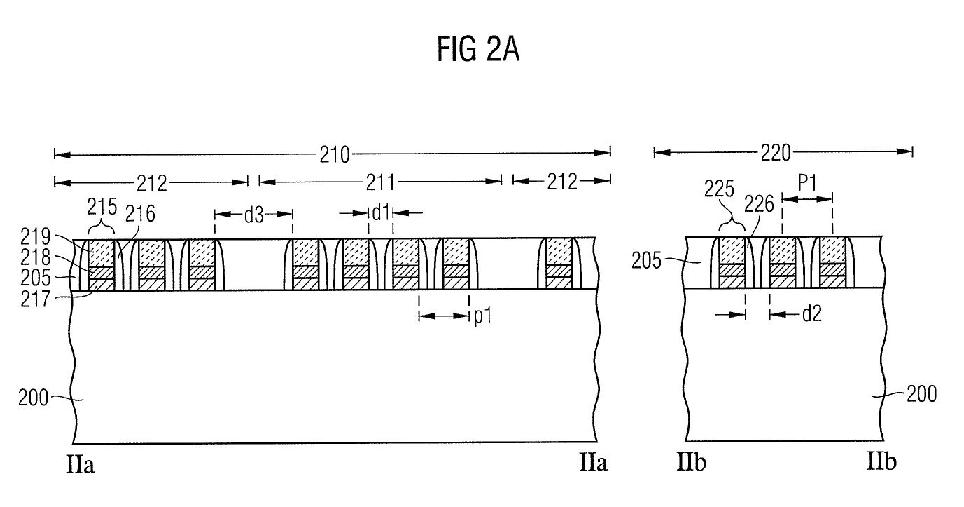

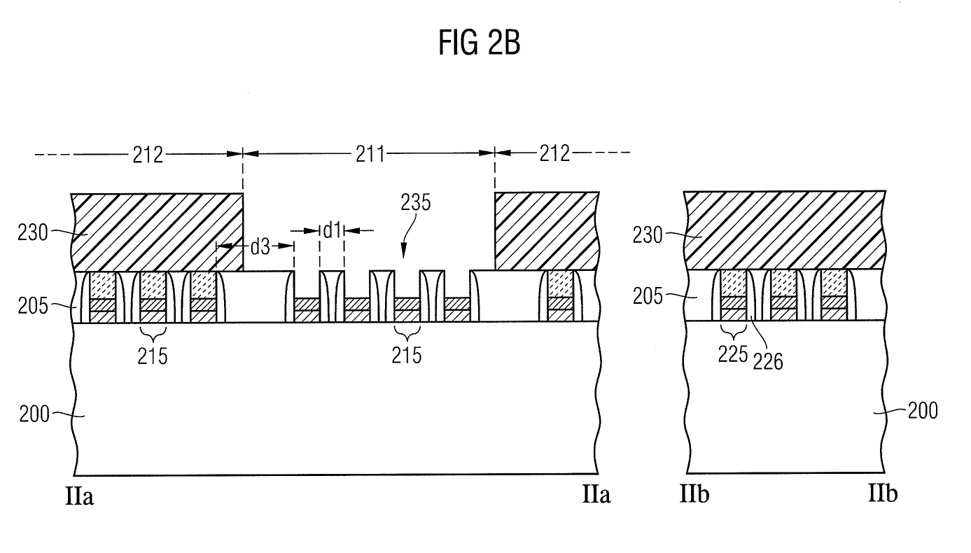

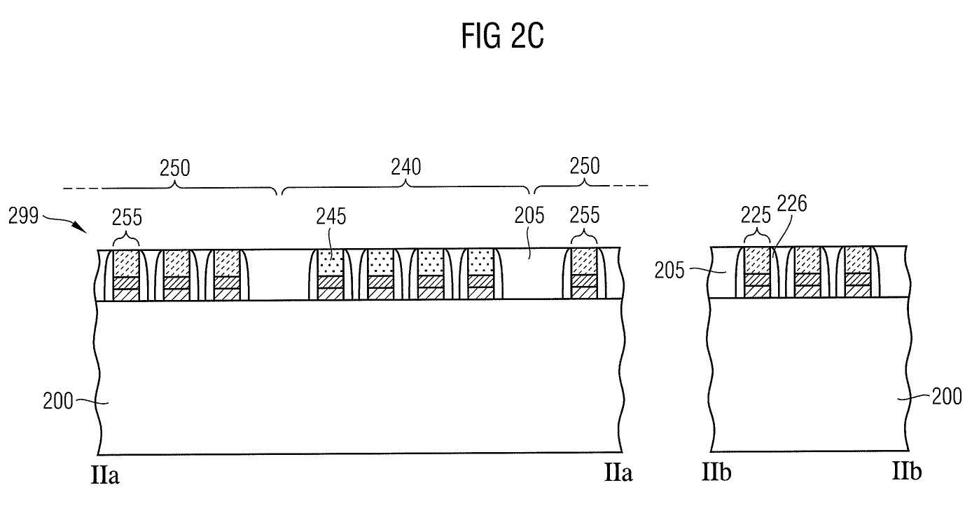

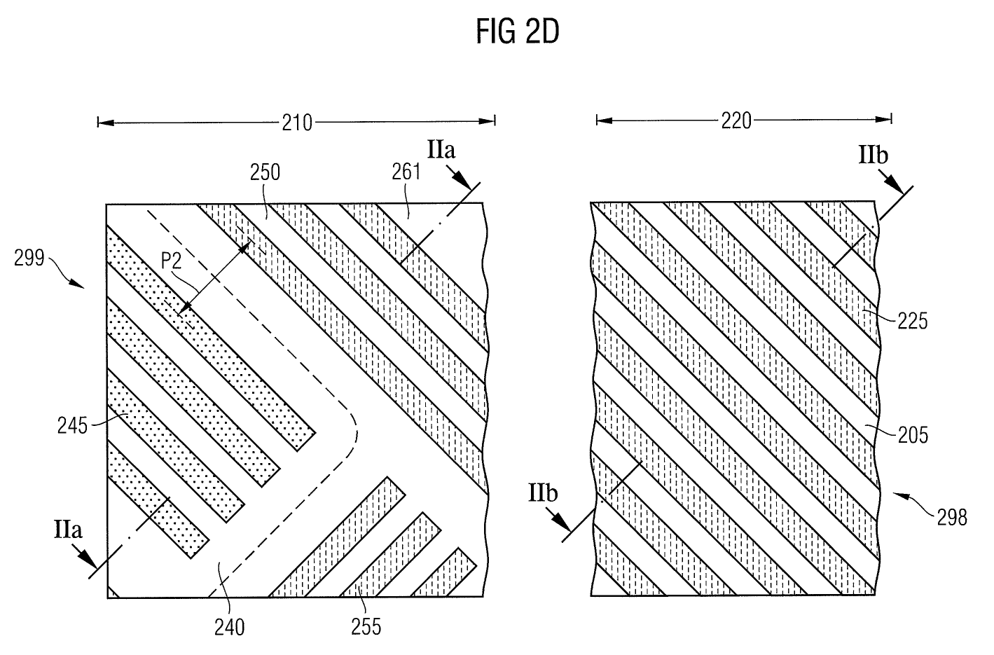

FIGS. 2A-2D refer to the formation of a metrology mark with stripe-like mark elements, for example, based on conductive lines or gate-lines, and mark portions that are spaced at a pitch that exceeds the pitch of the mark elements.

According to the left hand side of FIG. 2A, a first plurality of first structures 215, which may be arranged in a matrix, is formed in a first substrate section 210. A second plurality of first structures 225 is formed in a second substrate section 220 as illustrated on the right hand side of FIG. 2A. The first structures 215, 225 are arranged at the same pitch p1 in the first and second substrate sections 210, 220. The first structures 215 in the first substrate section 210 have a first distance d1 to each other and the first structures 225 in the second substrate section 220 have a second distance d2 to each other. The second distance d2 may be equal to the first distance d1 or may deviate from the first distance d1. The first structures 215, 225 may be complex structures, for example, a gate stack with a gate dielectric disposed on an underlying substrate 200, a heavily n-doped or heavily p-doped polysilicon layer 217 adjacent to the gate dielectric, a metal layer 218 on top of the polysilicon layer 217 and a nitride cap 219 on top of the metal layer 218. The first structures 215, 225 may include further barrier or adhesive, interface or auxiliary layers. Sidewall spacers 216 may extend along vertical sidewalls of the first structures 215, 225. The first structures 215, 225 may be embedded in an insulating dielectric 205. In the first substrate section 210, one or more of the first structures 215 may be skipped between neighboring sub-portions 211, 212 such that neighboring first structures 215 of neighboring sub-portions 211, 212 are spaced at a third distance d3 which is equal to the first distance d1 plus an integer multiple of the first pitch p1.

According to FIG. 2B, a mask 230 may be formed that covers both the second substrate section 220 and second sub-portions 212 of the first substrate section 210 and that leaves uncovered (i.e., exposed) first sub-portions 211 of the first substrate section 210. The mask 230 may be, for example, a hard mask or a resist mask and may be used as an etch mask, an implant mask or a mask blocking locally a chemical reaction. The allowable misalignment of openings 235 in the mask 230 is defined by the third distance d3. Using the mask 230 as an etch mask, a portion of the first structures 215 (e.g., the nitride cap 219), may be selectively removed from the material of the insulating dielectric 205.

According to FIG. 2C, the mask 230 may be removed and the voids formed in the exposed first structures 215 may be filled with a material delivering, for example, a high optical, inductive or capacitive contrast with respect to the insulating dielectric 205 and/or unaltered first structures 215 to form a metrology mark 299.

The metrology mark 299 comprises first elements 245, which emerge from those first structures 215 exposed through the openings 235 of the mask 230 of FIG. 2B in first mark portions 240 and second mark elements 255 corresponding to unaltered first structures 215 as shown in FIG. 2A in second mark portions 250. Within each mark portion 211, 212, neighboring first and second mark elements 245, 255 are arranged at the first pitch p1.

FIG. 2D refers to a planar top view on the substrate 200 as illustrated in FIG. 2C. On the left hand side, FIG. 2D illustrates a portion of a metrology mark 299 in a first substrate section 210, wherein the metrology mark 299 comprises first and second mark portions 240, 250 arranged in a regular pattern (e.g., a cross-shaped or box-shaped arrangement or in an arrangement of gratings). The mark portions 240, 250 may be, for example, rectangles. The first mark portions 240 comprise first elements 245 having signal response properties (e.g., a reflectivity versus an inspection radiation) that differ from that of second elements 255 arranged in the second mark portions 250.

The elements 245, 255 of the metrology mark 299 may be aligned with respect to a second plurality of first structures 225 in a second section 220 of the substrate 200 as illustrated on the right hand side of FIG. 2D, wherein the first structures 225 in the second substrate section 220 may be, for example, complex electric functional devices (e.g., multi-layered connectivity lines, word lines connecting and/or including gate electrodes of field effect transistors that are arranged in a first virtual regular grid, isolation trenches, line-shaped active areas or sub-structures thereof). The mark elements 245, 255 may be aligned with respect to the same virtual grid as the first structures 225 or to a second grid having the same mesh dimensions but being displaced with respect to the first grid. The signal contrast within each metrology mark 299 may be trimmed by selecting suitable materials, for example, with high optical, capacitive or inductive contrast, for upper portions of the first and second elements. The edges of the mark sections 240, 250 are defined by the grid aligned to which the elements 245, 255 are formed. The formation of mark elements 245, 255 between different mark sections 240, 250 may be suppressed in order to relax alignment requirements with regard to the mask 230 of FIG. 2B.

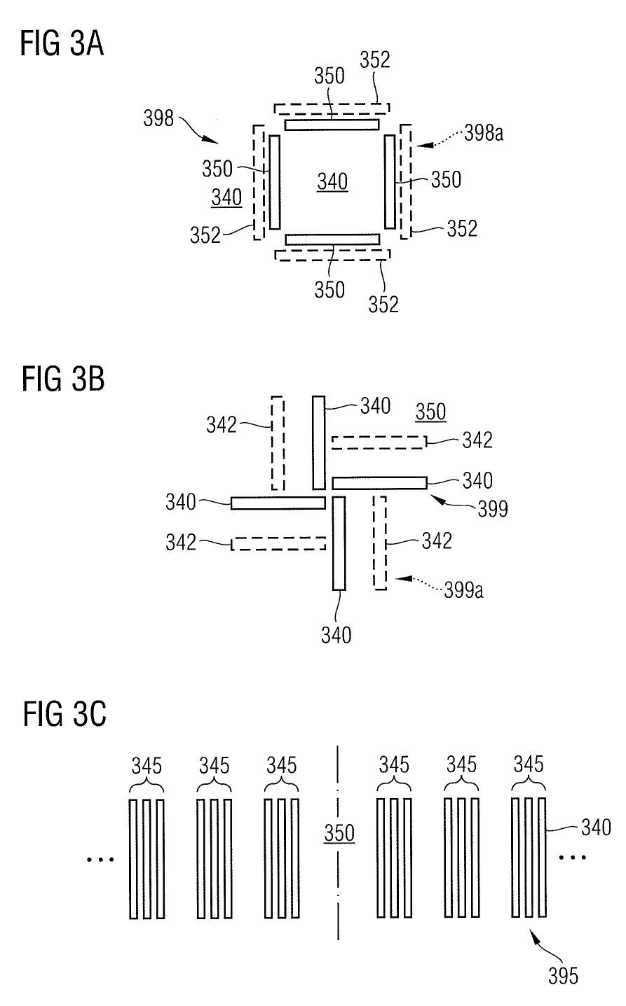

FIG. 3A refers to a metrology mark 398 based on a further arrangement of first and second mark portions 340, 350. The second mark portions 350 are arranged along the sides of a rectangle (e.g., a square). The first mark sections 340 are provided inside and outside the rectangle. The first and second mark portions 340, 350 may be exchanged against each other. The metrology mark 398 may be used as a first overlay mark. A second overlay mark 398a in another layer may comprise second mark portions 352 arranged along the sides of another rectangle with different dimensions. If the layers are perfectly aligned, the overlay marks 398, 398a are concentric.

According to the cross-shaped metrology mark 399 as illustrated in FIG. 3B, first mark portions 340 are arranged in lines that form a cross embedded in second mark portions 350, or vice versa. The metrology mark 399 may be used, for example, as a first overlay mark. A second overlay mark 399a, for example, in another layer may comprise further first mark portions 342 shifted to the first mark portions 340 along four different, orthogonal directions.

FIG. 3C refers to a metrology mark 395 which may be used as an alignment mark. The metrology mark 395 comprises stripe-shaped parallel first mark portions 340 arranged in groups 345 with, for example, three first mark portions 340. A mean distance between the groups 345 is significantly greater than a mean distance between first mark portions 340 within each group. The distances between the groups 345 may be equal or may change from group to group. The distances within each group 345 may be equal of may change from group to group and/or within each group. The first mark portions 340 of the metrology mark 396 may be arranged axis-symmetric to a center line running parallel to the first mark portions 340.

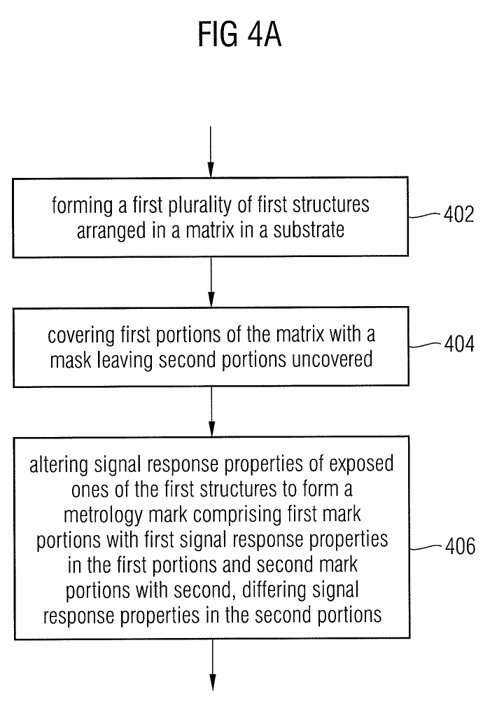

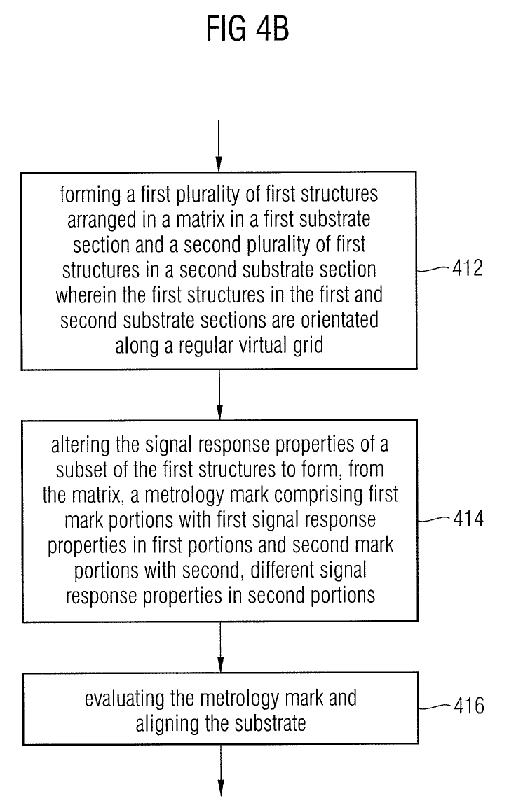

FIG. 4A is a simplified flow chart for illustrating a method of manufacturing an integrated circuit with a metrology mark according to another embodiment. In a substrate, a first plurality of first structures is formed, which are arranged in a matrix (402) and which are aligned to a virtual grid. First portions of the matrix are covered with a mask that leaves second portions of the matrix exposed (404). Then, the properties of exposed ones of the first structures are altered to form a metrology mark with first mark elements with first signal response properties in the first portions and second mark elements with second, different signal response properties in the second portions of the matrix (406). The signal may be, for example, radiation in the wavelength range of visible light or shorter, an electric field or a magnetic field. The mark portions are aligned to a grid which may be adjusted to functional structures in a further section of the substrate. The metrology mark may be formed self-aligned to a second plurality of first structures arranged in the second substrate section, in which electric functional devices are fabricated. The fabrication of the metrology mark is closely connected to the fabrication of those elements to which structures in further layers have to be aligned. A high signal contrast may be achieved for the metrology mark. The metrology mark may be measured (e.g., optically scanned) and the substrate may be aligned in response to the signal generated by the metrology mark.

The simplified flow chart of FIG. 4B refers to an alignment method, for example, for a wafer used in course of the manufacture of integrated circuits, according to another embodiment. On a workpiece (e.g., a wafer) a first plurality of first structures are arranged in a matrix in a first substrate section. A second plurality of first structures is formed, for example, contemporaneously with the first plurality, in a second substrate section, wherein the first structures in the first and second substrate sections may be oriented along the same regular, virtual grid (412) or along different grids having the same mesh dimensions. The signal response properties of a subset of the first structures is altered to form a metrology mark that comprises first mark portions with first signal response properties in first portions and second mark portions with second, different signal response properties in second portions (414). The metrology mark is measured (e.g., optically scanned). The wafer is aligned by evaluating the signal received from the metrology mark (416). An increased signal response contrast of the metrology mark results in a stronger signal from the metrology mark which eases the alignment process and/or facilitates a more precise aligning.

While the invention has been described in detail with reference to specific embodiments thereof, it will be apparent to one of ordinary skill in the art that various changes and modifications can be made therein without departing from the spirit and scope thereof. Accordingly, it is intended that the present invention covers the modifications and variations of this invention provided they come within the scope of the appended claims and their equivalents.

What is claimed is:

1. A method of manufacturing an integrated circuit, the method comprising:
(a) forming a first plurality of first structures arranged in a matrix in a substrate;
(b) covering portions of the matrix with a mask such that first portions of the matrix are exposed and second portions of the matrix are covered; and
(c) altering signal response properties of exposed ones of the first structures to form a metrology mark comprising first mark portions with first signal response properties in the first portions of the matrix and second mark portions with second signal response properties in the second portions of the matrix, the second response properties being different than the first response properties.

2. The method of claim 1, wherein the first and second mark portions are arranged in a regular pattern.

3. The method of claim 2, wherein:
the first structures have a first distance to each other and are arranged at a first pitch within each mark portion; and
the first and second mark portions have a second distance to each other that is equal to the first distance plus an integer multiple of the first pitch.

4. The method of claim 3, wherein the integer multiple is one.

5. The method of claim 1, wherein the first plurality of first structures aligned with respect to a first grid is formed in a first substrate section contemporaneously with a second plurality of first structures aligned with respect to a second grid in a second substrate section, the first and second grids having identical mesh dimensions, the method further comprising:
(d) aligning the substrate in dependence on a signal response of the metrology mark; and
(e) forming second structures aligned to the first structures in the second substrate section.

6. The method of claim 1, wherein (c) further comprises:
replacing a first material of an upper portion of the exposed ones of the first structures with a second material, wherein the second material provides a greater signal contrast with respect to a material surrounding the first structures than does the first material.

7. The method of claim 1, wherein (c) further comprises:
implanting impurities into a first material of an upper portion of the exposed ones of the first structures.

8. The method of claim 1, wherein (c) further comprises:
altering a first material of an upper portion of the exposed ones of the first structures to a second material via a chemical reaction, the second material being different from the first material.

9. The method of claim 1, wherein (c) further comprises:
generating a topology by removing at least an upper portion of the exposed ones of the first structures and depositing a material layer imaging the topology on its surface.

10. The method of claim 1, wherein (c) further comprises:
altering the reflectivity of the exposed ones of the first structures with respect to a radiation equal to or less than 1000 nm.

11. A method of manufacturing an integrated circuit, the method comprising:
(a) forming a first plurality of first structures arranged in a matrix in a first substrate section and a second plurality of first structures in a second substrate section wherein the first structures in the first and second substrate sections are oriented along grids having the same mesh dimensions;
(b) altering the signal response properties of a subset of the first structures to form, from the matrix, a metrology mark comprising first mark portions with first signal response properties in first portions of the matrix and second mark portions with second signal response properties in the second portions of the matrix, the second response properties being different than the first response properties; and
(c) evaluating the metrology mark and aligning the substrate based on the evaluation of the metrology mark.

12. The method of claim 11, wherein (b) further comprises:
covering portions of the matrix with a mask such that first portions of the matrix are exposed and second portions of the matrix are covered, wherein the first and second portions of the matrix are arranged in a regular pattern; and
altering the signal response properties of exposed ones of the first structures.

13. The method of claim 12, wherein (b) further comprises:
replacing a first material forming an upper portion of the exposed ones of the first structures of the first portions of the matrix with a second material, wherein the second material provides a greater signal contrast to a material surrounding the first structures than does the first material.

14. The method of claim 12, wherein (b) further comprises:
generating a topology by removing at least an upper portion of the exposed ones of the first structures and depositing a material layer imaging the topology on its surface.

15. The method of claim 11, wherein:
the first structures have a first distance to each other and are arranged at a first pitch within each mark portion; and
the first and second mark portions have a third distance to each other that is equal to the first distance plus an integer multiple of the first pitch.

16. The method of claim 15, wherein the integer multiple is one.

17. An integrated circuit, comprising:
a metrology mark that comprises first and second mark portions arranged in a regular pattern in a first substrate section, wherein signal response properties of first elements arranged in the first mark portions differ from that of first elements arranged in the second mark portions; and
a second plurality of first elements arranged in a second substrate section, wherein the first elements in the first and second substrate sections are aligned to one regular virtual grid.

18. The integrated circuit of claim 17, wherein the first and second mark portions are arranged in a regular pattern.

19. The integrated circuit of claim 18, wherein:
the first elements have a first distance to each other and are arranged at a first pitch within each first and second mark portion; and
the first and second mark portions have a third distance to each other that is equal to the first distance plus an integer multiple of the first pitch.

20. The integrated circuit of claim 19, wherein the integer multiple is one.

21. The integrated circuit of claim 17, wherein
upper sections of the first elements in the second mark portion comprise a first material; and
upper sections of the first elements in the first mark portion comprise a second material being different from the first material.

22. The integrated circuit of claim 17, wherein cross-section in the first and second substrate sections of the first elements are approximately the same.

23. The integrated circuit of claim 17, wherein lower sections of the first elements arranged below the upper sections are approximately identical in equivalent cross sections and material.
